(19) United States
(12) Patent Application Publication
(10) Pub. No.: US 2026/0099255 A1
(43) Pub. Date: Apr. 9, 2026

(54) CONSERVATION OF OVER PROVISIONING IN A MEMORY DEVICE

(71) Applicant: Microchip Technology Incorporated, Chandler, AZ (US)

(72) Inventors: Saswati Das, Milpitas, CA (US); Srinivas Yelisetti, Fremont, CA (US); Nian Niles Yang, Mountain View, CA (US)

(73) Assignee: Microchip Technology Incorporated, Chandler, AZ (US)

(21) Appl. No.: 19/049,820

(22) Filed: Feb. 10, 2025

Related U.S. Application Data
(60) Provisional application No. 63/703,348, filed on Oct. 4, 2024.

(51) Int. Cl. G06F 3/06

(52) U.S. Cl. CPC G06F 3/0616; G06F 3/0644; G06F 3/0659; G06F 3/0679

(57) ABSTRACT

A data storage system includes a controller, a memory, a non-volatile memory (NVM), and at least one processor. The NVM includes a logical unit (LUN). The LUN includes planes. Each plane includes a physical block. Each physical block includes a wordline (WL). Each WL includes a page. The pages include good pages and one or more bad pages. The physical blocks are organized into a multi-plane block. The multi-plane block includes a multi-plane WL. The multi-plane WL includes the WLs. The memory includes instructions stored thereon that, when executed by the at least one processor, cause the at least one processor to: identify the one or more bad pages; process user data to be written to the good pages; and write the user data to the good pages. Writing the user data to the good pages includes preventing writing of the user data to the one or more bad pages.

### CROSS-REFERENCE TO RELATED APPLICATIONS

The current patent application claims the benefit under 35 U.S.C. § 119(e) of the priority date of U.S. Provisional Application Ser. No. 63/703,348; titled “CONSERVATION OF OVER PROVISIONING IN NAND BASED SSD THROUGH IMPROVED PROGRAMMING SCHEME TO HANDLE BAD BLOCKS”; and filed October 4, 2024. The Provisional Application is hereby incorporated by reference, in its entirety, into the current patent application.

### TECHNICAL FIELD

Various examples of the present disclosure relate to conservation of over provisioning in a memory device through bad block handling.

### BACKGROUND

Multi-plane blocks in a memory device may include one or more bad blocks. Conventional memory device controllers may avoid writing data to multi-plane blocks that include bad blocks, which may significantly reduce over provisioning of the memory device over time. Writing data to bad blocks may produce errors, which in turn may increase write amplification of the memory device and increase a number of program/erase (P/E) cycles of the multi-plane blocks in an effort to correct the errors.

This background discussion is intended to provide information related to the present invention which is not necessarily prior art.

### SUMMARY OF THE INVENTION

According to various examples of the present disclosure, a data storage system may include a controller, a memory, a non-volatile memory (NVM), and at least one processor. The NVM may include a logical unit (LUN). The LUN may include a set of planes. Each of the planes may include a physical block. Each of the physical blocks may include a wordline (WL). Each WL may include a page. The pages may include good pages and one or more bad pages. The physical blocks may be organized into a multi-plane block. The multi-plane block may include a multi-plane wordline (WL). The multi-plane WL may include the WLs of the physical blocks. The instructions, when executed by the at least one processor, may cause the at least one processor to: identify the one or more bad pages of the multi-plane WL; process user data to be written to the good pages of the multi-plane WL; and write the processed user data to the good pages. Writing of the processed user data to the good pages may include preventing writing of the processed user data to the one or more bad pages.

According to various examples of the present disclosure, a computer implemented method may include: identifying one or more bad pages of a multi-plane WL of a multi-plane block of an NVM; processing user data to be written to good pages of the multi-plane WL; and writing the processed user data to the good pages. The NVM may include a LUN. The LUN may include a set of planes. Each of the planes may include a physical block. Each of the physical blocks may include a WL. Each of the WLs may include a page. The pages may include the good pages and the one or more bad pages. The physical blocks may be organized into the multi-plane block. The multi-plane WL may include the WLs of the physical blocks. Writing of the processed user data to the good pages may include preventing writing of the processed user data to the one or more bad pages.

According to various examples of the present disclosure, non-transitory media may include instructions stored thereon, that when executed by at least one processor, may cause the at least one processor to: identify one or more bad pages of a multi-plane WL of a multi-plane block of an NVM; process user data to be written to good pages of the multi-plane WL; and write the processed user data to the good pages. The NVM may include a LUN. The LUN may include a set of planes. Each of the planes may include a physical block. Each of the physical blocks may include a WL. Each of the WLs may include a page. The pages may include the good pages and the one or more bad pages. The physical blocks may be organized into the multi-plane block. The multi-plane WL may include the WLs of the physical blocks. Writing of the processed user data to the good pages may include preventing writing of the processed user data to the one or more bad pages.

This summary is not intended to identify essential features of the examples, and is not intended to be used to limit the scope of the claims. These and other aspects of the present examples are described below in greater detail.

### BRIEF DESCRIPTION OF THE DRAWINGS

FIG. 1 illustrates an example system for conservation of over provisioning through bad block handling;

FIG. 2 illustrates an example computing system of the system of FIG. 1 connected to a communication network;

FIG. 3 illustrates an example data storage system of the system of FIG. 1;

FIG. 4 illustrates an example non-volatile memory (NVM) media of the system of FIG. 1;

FIG. 5 illustrates an example multi-plane block of an NVM of the system of FIG. 1;

FIG. 6 illustrates an example multi-plane wordline (WL) of the multi-plane block of FIG. 5;

FIG. 7 illustrates an example data flow for conservation of over provisioning through bad block handling;

FIG. 8 illustrates another example data flow for conservation of over provisioning through bad block handling;

FIG. 9 illustrates an example method for conservation of over provisioning through bad block handling performed by the system of FIG. 1;

FIG. 10 illustrates an example method for conservation of over provisioning through bad block handling wherein processing of raw data is skipped;

FIG. 11 illustrates an example method for conservation of over provisioning through bad block handling wherein filler data is processed; and

FIG. 12 illustrates an example method for completing write operations in connection with conservation of overprovisioning through bad block handling.

Unless otherwise indicated, the figures provided herein are meant to illustrate features of examples of this disclosure. These features are believed to be applicable in a wide variety of systems comprising one or more examples of this disclosure. As such, the figures are not meant to include all conventional features known by those of ordinary skill in the art to be required for the practice of the examples disclosed herein.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, and process changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

Terms of relative location and direction (e.g., above, below, left, right, upper, lower) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

The following description may include examples to help enable one of ordinary skill in the art to practice the disclosed examples. The use of the terms "exemplary," "by example," and "for example," means that the related description is explanatory, and though the scope of the disclosure is intended to encompass the examples and legal equivalents, the use of such terms is not intended to limit the scope of an example or this disclosure to the specified components, operations, features, functions, or the like.

It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

In various examples of the present disclosure, a data storage system may include a memory device and a controller. The memory device may store data. The data storage system may be connected to a host system. In various examples, the data storage system may be connected to the host system by wired or wireless means. In various examples, the data storage system may be connected to more than one host system, such as in a multi-tenant environment, without limitation. The controller may be operable to manage storage and retrieval of data to and from the memory device. The host system may send data to the data storage system for storage in the memory device. The controller may process the data and issue commands to the memory device for storing the data in the memory device. The host system may send a read request to the data storage system. The read request may indicate data to be retrieved from the memory device and sent back to the host system. The controller may process the read request, retrieve the data from the memory device, process the retrieved data, and send the retrieved data to the host system.

In various examples, the memory device may be a solid state drive (SSD) including a plurality of non-volatile memory (NVM) media (e.g., NAND-based memory media) for data storage. In various examples, the NVM media may include chip enable (CE) ports which may also be referred to as targets. Examples may be used in single-level cell (SLC) systems, multi-level cell (MLC) systems, triple-level cell (TLC) systems, quad-level cell (QLC) systems, and penta-level cell (PLC) systems, without limitation. Applications may include consumer hard drives, high performance computing (HPC), data transfer for AI, and data center solutions (DCS), without limitation.

The NVM media may respectively include a local controller and a plurality of die. In various examples, the NVM media may respectively include two (2), four (4), eight (8), sixteen (16), twenty four (24), thirty two (32), or more die, without limitation. Each die may correspond to a logical unit (LUN). Each LUN may include a plurality of planes. Each LUN may include, for example, four (4), six (6), eight (8), or more planes, without limitation. Each plane may include a cache register, a page register, and a plurality of physical memory blocks.

When data is written to or retrieved from the NVM media, the data may be temporarily stored in one of the cache register and the page register. Each physical memory block may include a set of pages. The cache register and the page register may respectively have an equivalent data capacity of one page. Accordingly, data to be written to a first page may be temporarily stored in the cache register while data to be written to another page may be temporarily stored in the page register. Data to be read from a first page may be retrieved and temporarily stored in the cache register while data to be read from another page may be stored in the page register. Accordingly, the cache register and page register enable double buffering of data to reduce data programming and read times. Each page may include a plurality of cells. Each cell may include a transistor having a gate, a source, and a drain. Data bits may be written to the plurality of cells on a page-by-page basis. Data may be erased from the plurality of cells on a physical memory block basis.

The NVM media may additionally include a plurality of wordlines (WLs) and a plurality of bit lines (BLs). Generally, WLs connect the gates of each cell included in a row of cells. BLs may be connected to the drain of each cell. A row of cells having their gates connected by a WL may be referred to as a page. BLs can either connect the drain of a cell to the source of a cell in an adjacent row or to “ground” (e.g., true ground, 0V, Vcc, etc.). When a voltage is applied to a specific WL, cells included in that WL are accessible for writing/programming or reading. Data is stored in and/or transferred to/from cells during read/write operations via BLs. In other words, WLs effectively address rows of cells where data is being programmed to or read from, while BLs are highways on which data travel to reach the desired cell(s).

In various examples, the cells may include single-level cells (SLCs), multi-level cells (MLCs), triple-level cells (TLCs), quadruple-level cells (QLCs), and/or penta-level cells (PLCs), without limitation. Accordingly, the wordlines may be SLC wordlines, MLC wordlines, QLC wordlines and/or PLC wordlines, without limitation. In an example, a TLC multi-plane wordline may span four (4) planes. The four (4) planes may respectively include a lower page, a middle page, and an upper page of the wordline. The lower page, middle page, and upper page may correspond to a page including a string of TLCs. The TLC multi-plane wordline may be activated to write data to each of the upper, middle, and lower pages of each of the four (4) planes. Accordingly, an SLC wordline may be associated with one (1) page from each plane, an MLC wordline may include two pages (2) from each plane, a TLC wordline may include three (3) pages from each plane, a QLC wordline may include four (4) pages from each plane, and a PLC wordline may include five (5) pages from each plane.

In various examples, the physical blocks of each LUN may be organized into multi-plane blocks. A multi-plane block may include a set of blocks of a particular LUN. For example, a first block of a first plane of a first LUN, a first block of a second plane of the first LUN, a first block of a third plane of the first LUN, and a first block of a fourth plane of the first LUN may be organized into a multi-plane block. Accordingly, each LUN may include a number of multi-plane blocks equal to a number of physical blocks in one plane of a particular LUN, and each multi-plane block may include one (1) physical block from each plane of the particular LUN.

Each physical block of each multi-plane block may include a set of pages and a set of WLs corresponding to the set of pages. Accordingly, each plane of the multi-plane block may have a set of pages and corresponding set of WLs. The WLs may be organized into multi-plane WLs spanning the planes of a multi-plane block. Each multi-plane WL may include one (1) WL from each plane of the multi-plane block. For example, a multi-plane WL may include a first WL from a first plane of a multi-plane block, a first WL from a second plane of the multi-plane block, a first WL from a third plane of the multi-plane block, and a first WL from a fourth plane of the multi-plane block. The first WL of the first plane may correspond to a first page of the first plane, the first WL of the second plane may correspond to a first page of the second plane, and so on. For a TLC multi-plane WL, each page (e.g., the first page of the first plane, the first page of the second plane) may include a lower page, a middle page, and an upper page. Accordingly, each WL of a TLC multi-plane WL may include three (3) pages. A total number of pages in a TLC multi-plane WL is a number of pages in each plane multiplied by a number of planes. For example, a TLC multi-plane WL of a four (4) plane NVM may include a total of twelve (12) pages.

In various examples, the multi-plane blocks may be organized into virtual blocks (VBs). A VB may include one multi-plane block from each LUN of each NVM of the memory device. Each virtual block may include a set of virtual wordlines (VWL). Each VWL may include a set of multi-plane WLs. In various examples, the following data processing and programming operations may be performed on a VB/VWL basis rather than a multi-plane block/multi-plane WL basis without departing from the spirit of the present disclosure. Additionally, the following data processing and programming operations may be performed on a physical block/WL basis (e.g., writing user data to good pages of a physical block/WL while preventing writing the user data to bad page(s) of the physical block/WL) without departing from the spirit of the present disclosure.

In various examples, one or more multi-plane blocks may include one or more bad blocks corresponding to one or more of the planes of the multi-plane block. A bad block may be a physical memory block that produces a number of errors exceeding an error threshold and/or errors that meet a certain criteria, such as a number of uncorrectable errors and/or an amount of resources used to correct errors produced by the bad block. A multi-plane block including bad blocks may also include good blocks. A good block may be a healthy physical block that does not produce errors exceeding the error threshold or meeting the certain criteria. The bad blocks may or may not be uniformly distributed across the planes of the multi-plane blocks. For example, two (2) multi-plane blocks of a given LUN may each include a bad block. The bad block of the first multi-plane block may be in a first plane of the LUN. The bad block of the second multi-plane block may be in a second plane of the LUN.

In various examples, the controller may preserve over provisioning in the memory device by writing user data to good blocks of a multi-plane block while preventing writing of the user data to bad blocks of the multi-plane block. Over provisioning is data storage capacity of the memory device reserved for internal use. The reserved data storage capacity may be used for storing firmware metadata and as extra storage utilized during garbage collection (GC) operations. Firmware metadata may include a logical-to-physical (L2P) mapping table, physical block management data, bad block information, firmware images, and/or self-monitoring, analysis, and reporting technology (SMART) information, without limitation. GC may include copying valid data from a first virtual block and writing the valid data to a second virtual block. Any invalid data from the first virtual block may then be erased. The first virtual block may be free to store new data after the invalid data is erased. In various examples, GC operations may be applied to multi-plane blocks on an individual basis or on a virtual block basis. A virtual block may include a collection of multi-plane blocks. For example, a virtual block may include one (1) multi-plane block from each LUN.

In various examples, the controller may receive a write request from the host system. The write request may include user data to be written to an NVM of the memory device. The user data may include, for example, media (e.g., photos, videos, and/or audio), system information data, application data, sensor data, document data, recordkeeping data, machine learning/artificial intelligence data, gaming system data, data pertaining to internal operations of the host system, and the like, without limitation. The controller may determine to write the user data to a multi-plane WL of the multi-plane block of the NVM. The multi-plane block may include good blocks and one or more bad blocks. Accordingly, the multi-plane WL may include good pages and one or more bad pages. The good pages may be pages of the good blocks. The bad page(s) may be page(s) of the bad block(s).

The controller may identify the good pages and/or the bad page(s) of the multi-plane WL. The controller may include data processors. The controller may process the user data using the data processors to generate processed user data. Subsequent to processing the user data, the controller may temporarily store the processed user data in the buffer.

In various examples, the controller may generate raw data. The raw data may not be processed by the data processors. The raw data may have a value corresponding to an erased state of the bad page(s). The bad page(s) may be in the erased state before the raw data is issued. The controller may interleave the raw data with the processed user data. The processed user data and raw data may be temporarily stored in the buffer before or after interleaving.

In various examples, the controller may issue the processed user data and the raw data to a set of page registers of a multi-plane WL of a multi-plane block of a LUN of the memory device. The multi-plane block may include the set of page registers. Each of the page registers may correspond to the pages of one (1) plane. The processed user data may be transferred to a first subset of the page registers corresponding to the good pages. The raw data may be transferred to a second subset of the page registers corresponding to the bad page(s).

The controller may program the user data to the good pages. The raw data may be issued to the bad page(s). After programming operations are completed, the user data may be stored in the good pages, and the bad pages may remain in the erased state. Consequently, the bad page(s) are effectively skipped over when programming the user data to the good pages.

In various examples, the controller may generate filler data. The filler data may have a fixed data pattern. The filler data may be used in place of or as an alternative to the raw data if the controller is unable to skip processing of the raw data by the data processors or skipping of processing of the raw data is undesirable. The controller may process the filler data by the data processors to generate filler data. The controller may process the user data in the same manner. The controller may transfer the processed user data to a first subset of the page registers corresponding to the good pages and transfer the processed filler data to a second subset of the page registers corresponding to the bad page(s).

The controller may program the processed user data to the good pages and program the processed filler data to the bad page(s). Accordingly, the processed user data is only written to the good pages, and the bad page(s) may be programmed to the fixed data pattern of the processed filler data. Consequently, the bad page(s) of the multi-plane block are effectively skipped when writing user data to the good pages of the multi-plane block.

Preventing writing of the processed user data to the bad page(s) may conserve over provisioning of the memory device by continuing to utilize good pages in a multi-plane block having good pages and bad pages. Conserving over provisioning may reduce write amplification of the memory device, avoid an increased number of P/E cycles caused by reduced over provisioning to extend the lifetime of the memory device, and maintain efficient write performance while effectively handling bad blocks.

In various examples, the controller may poll a program status of the good pages while programming the processed user data to the good pages. The controller may skip polling a program status of the bad page(s). Accordingly, the controller may determine whether the processed user data has been successfully written to the good pages. When the processed user data has been successfully written to the good pages, the controller my terminate write operations. Polling the program status of only the good pages may reduce program time and improve program efficiency by skipping polling of the bad page(s).

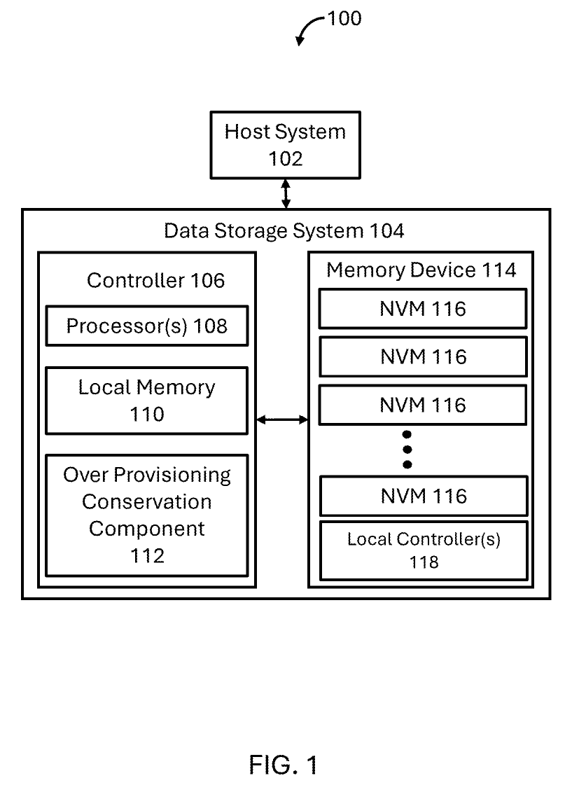

FIG. 1 illustrates an example system 100 including a host system 102 and a data storage system 104. The data storage system 104 may include a controller 106. The controller 106 may include a processor 108, a local memory 110, and an over provisioning conservation component 112. The data storage system 104 may also include a memory device 114. The memory device 114 may include a plurality of NVM media 116 and one or more local controller(s) 118.

In various examples, a read or write request may be received from the host system 102 via a peripheral component interconnect express (PCIe) interface that connects the data storage system 104 to servers or CPUs. PCIe is a standardized interface for motherboard components. The controller 106 may use logical block addresses (LBAs) and physical block addresses (PBAs) to facilitate access for data storage in and retrieval from the NVM media 116. LBAs are an abstraction to allow the operating system to interact with the NVM media 116, and PBAs represent the actual hardware locations within the NVM media 116. To facilitate interacting with the NVM media 116, the controller 106 may create an entry or record that assigns an LBA to a PBA. To keep track of all such LBA-to-PBA assignments, the controller 106 may use a logical-to-physical (L2P) mapping table. The L2P table may be uploaded to the local memory 110 so that it can be more quickly accessed and updated by the controller 106. In various examples, the local memory 110 may include a synchronous dynamic random access memory (SDRAM), without limitation.

When a data request is received from the host system 102, the controller 106 references the L2P mapping table to determine the PBA within the NVM media 116 corresponding to a desired LBA. Once the PBA is determined, the controller 106 accesses the appropriate NVM media 116 to write or read the data. Access to the NVM media 116 may be via a flash physical (PHY) interface. The controller 106 may employ an error correction code (ECC) operation during encoding and decoding data to detect and correct errors and enhance data integrity. Additionally, the memory device 114 may support a direct memory access (DMA) operation enabling data to be written from the host system 102 directly to the NVM media 116 and read from the NVM media 116 directly to the host system 102. Certain commands may be issued to the controller 106 or the local controller(s) 118 using the host command layer, or non-volatile memory express management interface (NVMe-MI).

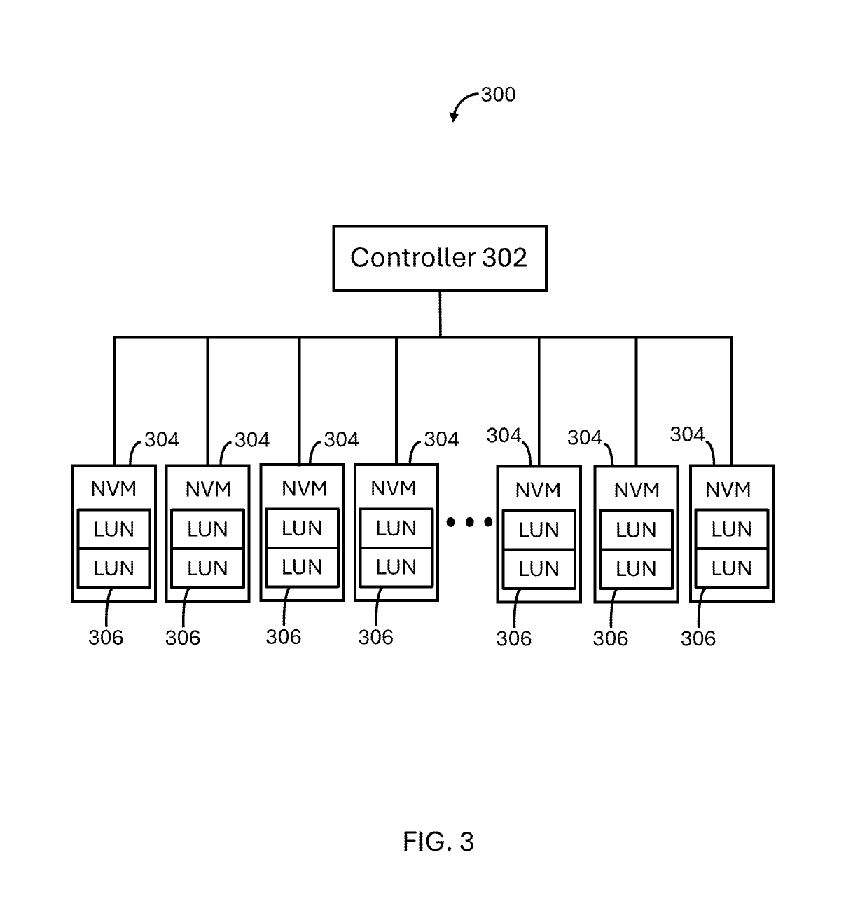

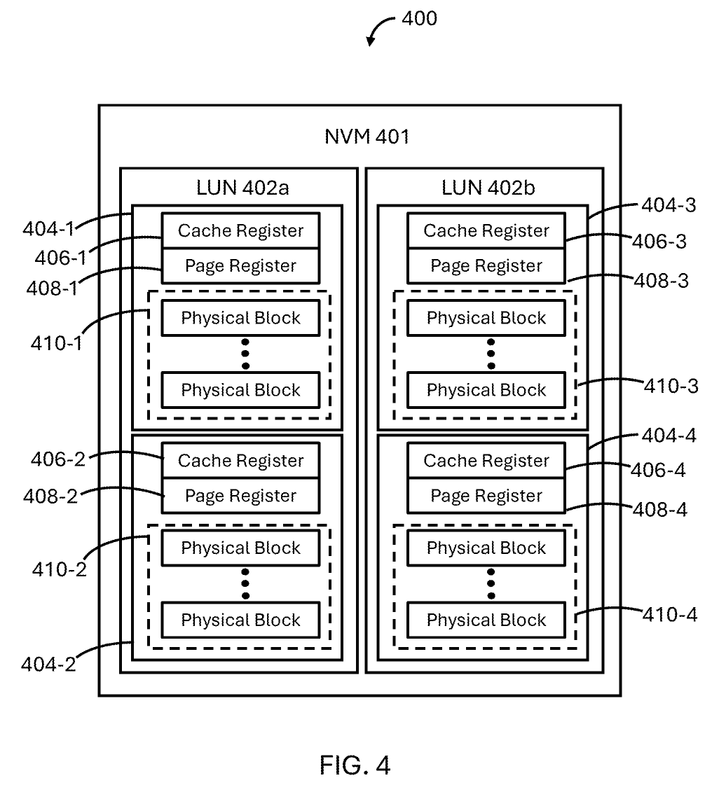

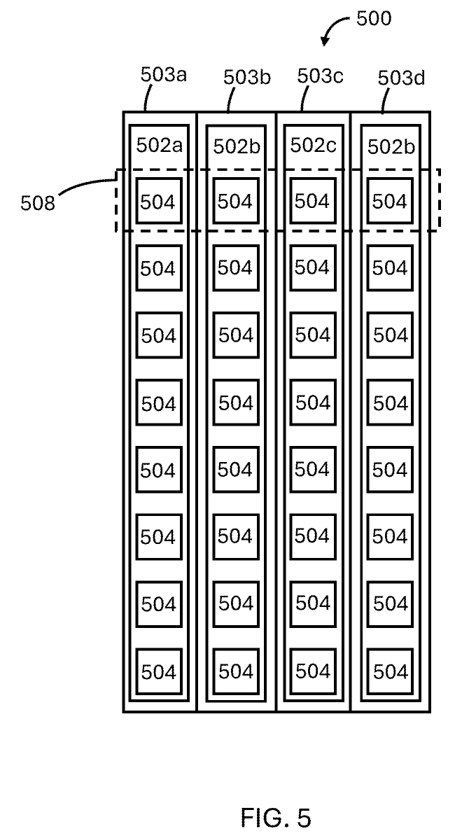

Each of the NVM media 116 may include a plurality of LUNs (e.g., the LUNs 306 of FIG. 3). Each LUN may include a plurality of planes (e.g., the planes 404-1, 4042, 4043, 404-4 of FIG. 4). Each plane may include a plurality of physical blocks (e.g., the physical blocks 410-1, 410-2, 410-3, 410-4 of FIG. 4). Each block may include a set of pages (e.g., the pages 504 of FIG. 5). Each physical block may include a set of WLs corresponding to the pages. Respective ones of the physical blocks may be organized into a multi-plane block (e.g., the multi-plane block 500 of FIG. 5). Each multi-plane block may include one (1) physical block from each plane of one (1) LUN. Each multi-plane block may include a set of multi-plane WLs (e.g., the multi-plane WL 508 of FIG. 5). Each multi-plane WL may include corresponding WLs of the physical blocks included in a multi-plane block such that each multi-plane WL includes one (1) WL from each plane of the multi-plane block. User data may be written to the pages of a multi-plane WL.

Respective ones of the multi-plane blocks may include good blocks and one or more bad blocks. Accordingly, each multi-plane WL may include good pages corresponding to the good blocks, and one or more bad pages corresponding to the bad block(s). The over provisioning conservation component 112 may conserve over provisioning by writing user data to good pages of a given multi-plane WL while preventing the user data from being written to the bad page(s) of the multi-plane WL.

In various examples, the over provisioning conservation component 112 may preserve over provisioning in the memory device 114 by writing user data to good blocks of multi-plane blocks of the NVM media 116 of while preventing writing of the user data to bad blocks of the multi-plane blocks.

In various examples, the over provisioning conservation component 112 may receive a write request from the host system 102. The write request may include user data to be written to an NVM media 116 of the memory device 114. The user data may include, for example, media (e.g., photos, videos, and/or audio), system information data, application data, sensor data, document data, recordkeeping data, machine learning/artificial intelligence data, gaming system data, data pertaining to internal operations of the host system, and the like, without limitation. The over provisioning conservation component 112 may determine to write the user data to a multi-plane WL of a multi-plane block of the NVM media 116. The multi-plane block may include good blocks and one or more bad blocks. Accordingly, the multi-plane WL may include good pages and one or more bad pages. The good pages may be pages of the good blocks. The bad page(s) may be page(s) of the bad block(s).

The over provisioning conservation component 112 may identify the good pages and the bad page(s) of the multi-plane WL. The good and bad page(s) may be identified by querying bad block information stored in the memory device. The over provisioning conservation component 112 may detect bad blocks based on error information produced by the physical blocks. The over provisioning conservation component 112 may update the bad block information to include newly detected bad blocks each time a bad block is detected.

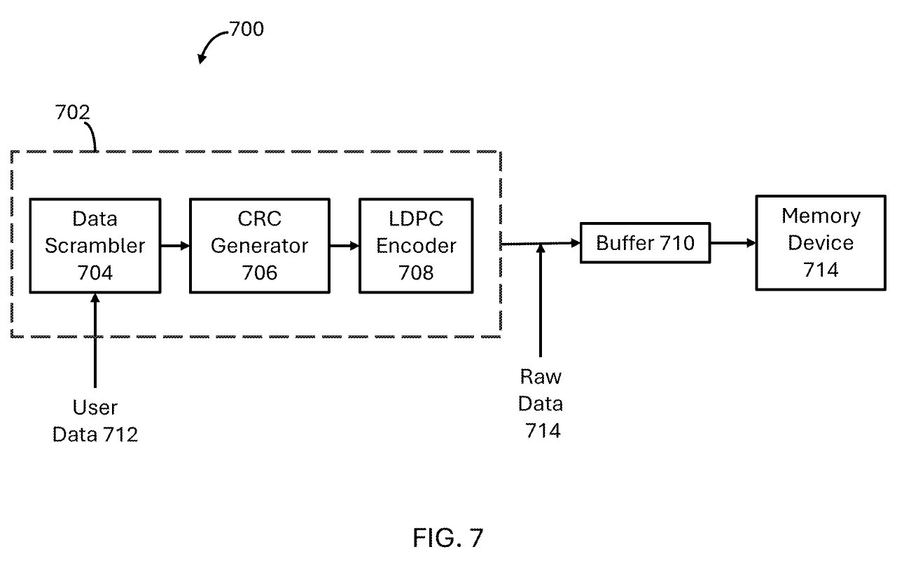

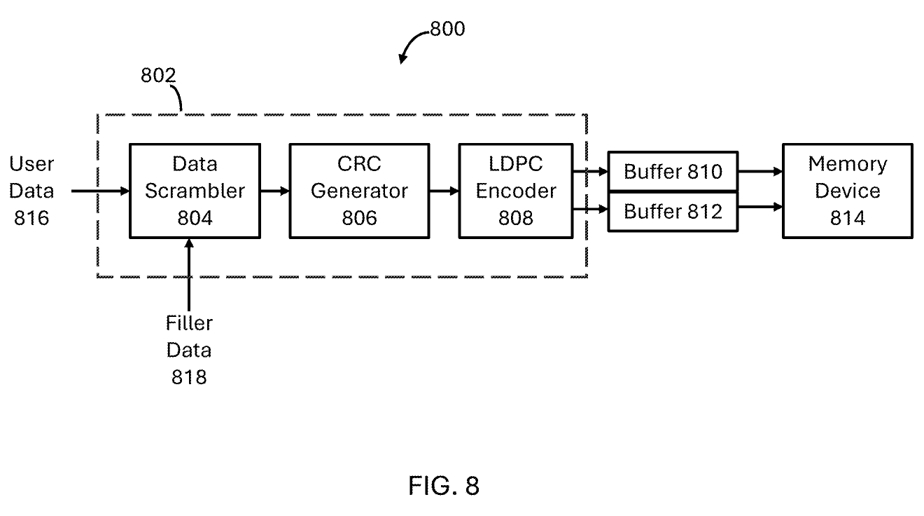

The over provisioning conservation component 112 may include data processors. The data processors may include a data scrambler, a CRC generator, and an LDPC encoder (as shown in FIG. 7 and FIG. 8). The over provisioning conservation component 112 may process the user data using the data scrambler, the CRC generator, and the LDPC encoder. The data scrambler may scramble bits of the user data. The CRC generator may add CRC bits to the user data. The LDPC encoder may add LDPC bits to the user data. The over provisioning conservation component 112 may additionally include a buffer. Subsequent to processing the user data, the over provisioning conservation component 112 may temporarily store the processed user data in the buffer.

In various examples, the over provisioning conservation component 112 may generate raw data. The raw data may not be processed by any of the data scrambler, the CRC generator, or the LDPC encoder (i.e., data processing is skipped for the raw data). The raw data may have a value corresponding to an erased state of the bad page(s). The bad page(s) may be in the erased state before the raw data is issued to the bad page(s). For example, in a TLC, the erased state may correspond to a bit value of “111”. The over provisioning conservation component 112 may interleave the raw data with the processed user data such that the processed user data will be issued to the good pages and the raw data will be issued to the bad page(s). The processed user data and raw data may be temporarily stored in the buffer before or after interleaving.

In various examples, the over provisioning conservation component 112 may issue a random data input command sequence to transfer the processed user data and the raw data to a multi-plane WL of a multi-plane block of a LUN of the memory device 114. The multi-plane block may include page registers corresponding to respective pages of each plane of the LUN. The random data input command sequence may include a protected bulk data transfer corresponding to the processed user data and a raw bulk data transfer corresponding to the raw data. The processed user data may be transferred to a first subset of page registers of the LUN corresponding to the good pages by the protected bulk data transfer command. The raw data may be transferred to a second subset of the page register(s) of the LUN corresponding to the bad page(s) by the raw bulk data transfer command.

The over provisioning conservation component 112 may issue a multi-plane full program sequence to write the user data to the good pages. The raw data may be issued to the bad page(s) as part of the multi-plane full program sequence. After the multi-plane full program sequence is executed, the user data may be stored in the good pages, and the bad pages may remain in the erased state. Because the bit value of the raw data is the same as the bit value of the erased state of the bad page(s), no programming operations will occur at the bad page(s). Consequently, the bad page(s) are effectively skipped over when programming the user data to the good pages. Preventing writing of the processed user data to the bad page(s) may conserve over provisioning of the memory device 114 by continuing to utilize good pages in a multi-plane block having good pages and bad pages. Conserving over providing may reduce write amplification of the memory device 114, avoided increased P/E cycles caused by reduced over provisioning to extend the lifetime of the memory device 114, and maintain efficient write performance while effectively handling bad blocks.

In various examples, the over provisioning conservation component 112 may generate filler data. The filler data may have a fixed data pattern, such as all zeros (0s) or all ones (1s). The filler data may be used in place of the raw data if the over provisioning conservation component 112 is unable to skip processing of the raw data by the data scrambler, CRC generator, and LDPC encoder. For example, some legacy controllers may not be capable of interleaving raw data with processed data. The over provisioning conservation component 112 may scramble data bits of the filler data by the data scrambler, add CRC bits to the filler data by the CRC generator, and add LDPC bits to the filler data by the LDPC encoder. The over provisioning conservation component 112 may process the user data in the same manner. The processed user data may be temporarily stored in a first buffer. The processed filler data may be temporarily stored in a second buffer. The over provisioning conservation component 112 may issue a protected bulk data transfer command sequence to transfer the processed user data to a first subset of the page registers of the multi-plane block corresponding to the good pages and to transfer the processed filler data to a second subset of the page registers of the multi-plane block corresponding to the bad page(s).

The over provisioning conservation component 112 may issue a multi-plane full program command sequence to program the processed user data to the good pages and program the processed filler data to the bad page(s). Accordingly, the processed user data is only written to the good pages, and the bad page(s) may be programmed to the fixed data pattern of the processed filler data. Consequently, the bad page(s) of the multi-plane block are effectively skipped when writing user data to the good pages of the multi-plane block. Preventing writing of the processed user data to the bad page(s) may conserve over provisioning of the memory device 114 by continuing to utilize good pages in a multi-plane block having good pages and bad pages while avoiding issues caused by bad pages.

Conserving over providing may reduce write amplification of the memory device 114, avoided an increased number of P/E cycles caused by reduced over provisioning to extend the lifetime of the memory device 114, and maintain efficient write performance while effectively handling bad blocks.

In various examples, the over provisioning conservation component 112 may poll a program status of the good pages of the multi-plane block while executing the multi-plane full program sequence. The over provisioning conservation component 112 may skip polling a program status of the bad page(s). Accordingly, the over provisioning conservation component 112 may determine whether the processed user data has been successfully written to the good pages based on the polled program status of the good pages. When the processed user data has been successfully written to the good pages of the multi-plane WL of the multi-plane block, the over provisioning conservation component 112 my terminate write operations on the multi-plane WL. Polling the program status of only the good pages may reduce program time and improve program efficiency by skipping polling of the bad page(s).

In various examples, instructions for executing the over provisioning conservation component 112 may be stored in the local memory 110. Some or all functions of the over provisioning conservation component 112 may be executed by the processor 108, the local controller(s) 118, other circuitry of the controller 106 and/or memory device 114, and/or a combination thereof.

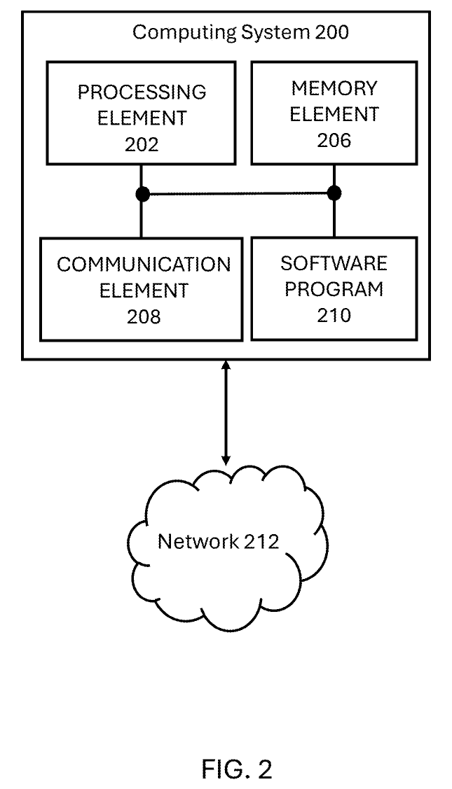

FIG. 2 illustrates a computing system 200 connected to a communication network 212. The computing system 200 may include at least one processing element 202, at least one memory element 206, a communication element 208, and a software program 210. In various examples, the computing system 200 may be a host system (e.g., the host system 102 of FIG. 1) and/or a data storage system (e.g., the data storage system 104 of FIG. 1), without limitation.

The software program 210 may be configured with instructions for performing and/or enabling performance of at least some of the steps set forth herein. In an embodiment, the software program 210 comprises instructions stored on computer-readable media of memory element 206. In various examples, the software program 210 may include instructions for performing operations of the over provisioning conservation component 112 discussed with reference to FIG. 1.

The communication network 212 generally allows communication between the computing system 200 and another computing device, such as between a remote host system (e.g., the host system 102), a local host system, and/or a data storage system (e.g., the data storage system 104 of FIG. 1), without limitation.

The communication network 212 may include the Internet, cellular communication networks, local area networks, metro area networks, wide area networks, cloud networks, plain old telephone service (POTS) networks, and the like, or combinations thereof. The communication network 212 may be wired, wireless, or combinations thereof and may include components such as modems, gateways, switches, routers, hubs, access points, repeaters, towers, and the like. The computing system 200 may, for example, connect to the communication network 212 either through wires, such as electrical cables or fiber optic cables, or wirelessly, such as RF communication using wireless standards such as cellular 2G, 3G, 4G or 5G, Institute of Electrical and Electronics Engineers (IEEE) 802.11 standards such as WiFi, IEEE 802.16 standards such as WiMAX, Bluetooth™, or combinations thereof.

The communication element 208 generally allows communication between the computing system 200 and the communication network 212. The communication element 208 may include signal or data transmitting and receiving circuits, such as antennas, amplifiers, filters, mixers, oscillators, digital signal processors (DSPs), and the like. The communication element 208 may establish communication wirelessly by utilizing radio frequency (RF) signals and/or data that comply with communication standards such as cellular 2G, 3G, 4G or 5G, Institute of Electrical and Electronics Engineers (IEEE) 802.11 standard, such as WiFi, IEEE 802.16 standard, such as WiMAX, Bluetooth™, or combinations thereof. In addition, the communication element 208 may utilize communication standards such as ANT, ANT+, Bluetooth™ low energy (BLE), the industrial, scientific, and medical (ISM) band at 2.4 gigahertz (GHz), or the like. Alternatively, or in addition, the communication element 208 may establish communication through connectors or couplers that receive metal conductor wires or cables, like Cat 6 or coax cable, which are compatible with networking technologies such as ethernet. In certain embodiments, the communication element 208 may also couple with optical fiber cables. The communication element 208 may respectively be in communication with the processing element 202 and/or the memory element 206.

The memory element 206 may include electronic hardware data storage components such as read-only memory (ROM), programmable ROM, erasable programmable ROM, random-access memory (RAM) such as static RAM (SRAM) or dynamic RAM (DRAM), solid state drives (SSDs), cache memory, hard disks, floppy disks, optical disks, flash memory, thumb drives, universal serial bus (USB) drives, or the like, or combinations thereof. In some embodiments, the memory element 206 may be embedded in, or packaged in the same package as, the processing element 202. The memory element 206 may include, or may constitute, a “computer-readable medium.” The memory element 206 may store the instructions, code, code segments, software, firmware, programs, applications, apps, services, daemons, or the like that are executed by the processing element 202. In an embodiment, the memory element 206 respectively store the software applications/program 210. The memory element 206 may also store settings, data, documents, sound files, photographs, movies, images, databases, and the like. In various examples, the memory element 206 may include a first memory component (e.g., the local memory 110 of FIG. 1) and one or more SSDs (e.g., the memory device 114 of FIG. 1).

The processing element 202 may include electronic hardware components such as processors. The processing element 202 may include digital processing unit(s). The processing element 202 may include microprocessors (single-core and multi-core), microcontrollers, digital signal processors (DSPs), field-programmable gate arrays (FPGAs), analog and/or digital application-specific integrated circuits (ASICs), or the like, or combinations thereof. The processing element 202 may generally execute, process, or run instructions, code, code segments, software, firmware, programs, applications, apps, processes, services, daemons, or the like. For instance, the processing element 202 may respectively execute the software applications/program 210. The processing element 202 may also include hardware components such as finite-state machines, sequential and combinational logic, and other electronic circuits that can perform the functions necessary for the operation of the current disclosure. The processing element 202 may be in communication with the other electronic components through serial or parallel links that include universal busses, address busses, data busses, control lines, and the like.

FIG. 3 illustrates an example data storage system 300 including a controller 302 and a plurality of NVM media 304. In various examples, the data storage system 300 may correspond to the data storage system 104 of FIG. 1, the controller 302 may correspond to the controller 106 of FIG. 1, and the NVM media 304 may correspond to the NVM media 116 of FIG. 1, without limitation. In various examples, the NVM media 304 may each include two LUNs 306. It would be appreciated by one of ordinary skill in the art that each NVM 304 may include more than two LUNs, without limitation. Each LUN 306 may correspond to a respective die of the NVM media 304. In various examples, the controller 302 may write incoming data to more than one NVM media 304 in parallel. The NVM media 304 may write incoming data to more than one LUN 306 in parallel. Each LUN 306 may include a set of multi-plane blocks.

FIG. 4 illustrates an example NVM media 400. The NVM 400 may correspond to the NVM media 116 of FIG. 1 and/or the NVM media 304 of FIG. 3, without limitation. The NVM media 400 may include a LUN 402a and a LUN 402b. The LUN 402a may include a plane 404-1 and a plane 404-2. The plane 404-1 may include a cache register 406-1, a page register 408-1, and physical blocks 410-1. The plane 404-2 may include a cache register 406-2, a page register 408-2, and physical blocks 410-2. The LUN 402b may include a plane 404-3 and a plane 404-4. The plane 404-3 may include a cache register 406-3, a page register 408-3, and physical blocks 410-3. The plane 404-4 may include a cache register 406-4, a page register 408-4, and physical blocks 410-4. It would be appreciated by one of ordinary skill in the art that the NVM media 400 may include more than two (2) die and each die may include more than two (2) planes. In various examples, the NVM media 400 may include two (2), four (4), eight (8), sixteen (16), twenty four (24), thirty two (32), or more die, without limitation. Each die may include, for example, four (4), six (6), eight (8), or more planes, without limitation.

When data is written to or retrieved from the LUN 402aor the LUN 402b, the data may be temporarily stored in one of the cache registers 406-1, 406-2, 406-3, 406-4 and/or the page registers 408-1, 408-2, 408-3, 408-4. The cache registers 406-1, 406-2, 406-3, 406-4 and the page registers 408-1, 408-2, 408-3, 408-4 may respectively have an equivalent data capacity of one page. Accordingly, data to be written to one page of one of the physical blocks 410-1 may be temporarily stored in the cache register 406-1 while data to be written to another page of one of the physical blocks 410-1 may be temporarily stored in the page register 408-1. Data being read from a page of one of the physical blocks 410-1 may be retrieved and temporarily stored in the page register 408-1 while data read from a page of another one of the physical blocks 410-1 may transferred from the cache register 406-1 to a controller (e.g., the controller 104 ofFIG. 1). Accordingly, the cache register and page register enable double buffering of data to reduce data programming and read times. Each page may include a plurality of cells. Data bits may be written to the plurality of cells on a WL-by-WL basis. Data may be erased from the plurality of cells on a physical block basis.

In various examples, a first set of multi-plane blocks may be formed across the planes 404-1, 404-2 of the LUN 402aand a second set of multi-plane blocks may be formed across the planes 404-3, 404-4 of the LUN 402b. Each multi-plane block of the first set of multi-plane blocks may include one (1) physical block from the plane 404-1 and one (1) physical block from the plane 404-2. Each multi-plane block of the second set of multi-plane blocks may include one (1) physical block from the plane 404-3 and one (1) physical block from the plane 404-4. For example, a first multi-plane block may include a first one of the physical blocks 410-1 and a first one of the physical blocks 410-2. A second multi-plane block may include a first one of the physical blocks 410-3 and a first one of the physical blocks 410-4.

Each multi-plane block may include a multi-plane WL (e.g., the multi-plane WL 508 of FIG. 5). Accordingly, each set of multi-plane blocks may include a corresponding set of multi-plane WLs. For example, a first multi-plane WL may include a WL of one of the physical blocks 410-1 and a WL of one of the physical blocks 410-2. A second multi-plane WL may include a WL from one of the physical blocks 410-3 and a WL of one of the physical blocks 410-4. In an example, a multi-plane WL may include one (1) WL from each plane 404-1, 404-2, 404-3, 404-4. A multi-plane block may include one (1) physical block 410-1 from the plane 404-1, one (1) physical block 410-2 from the plane 404-2, one (1) physical block 410-3 from the plane 404-3, and one (1) physical block 410-4 from the plane 404-4. The WLs or physical blocks that make up a multi-plane WL or multi-page block may or may not be in a same location of each plane of a corresponding one of the LUNs 402a, 402b.

FIG. 5 illustrates a multi-plane block 500 of an NVM (e.g., the NVM 116 of FIG. 1). The multi-plane block may include physical blocks 502a, 502b, 502c, 502d. The physical blocks 502a, 502b, 502c, 502d may be included in a set of planes 503a, 503b, 503c, 503d. Each physical block 502a, 502b, 502c, 502d may include a set of pages 504. A multi-plane WL 508 may be formed to include a page 504 of each physical block 502a, 502b, 502c, 502d.

In various examples one or more of the physical blocks 502a, 502b, 502c, 502d may be bad blocks. The remaining physical blocks 502a, 502b, 502c, 502d may be good blocks. Accordingly, the pages 504 may include good pages and one or more bad pages. The good pages may be included in the good blocks of the physical blocks 502a, 502b, 502c, 502d. The one or more bad pages may be included in the one or more bad blocks of the physical blocks 502a, 502b, 502c, 502d. Consequently, the multi-plane WL 508 may include good pages and one or more bad pages.

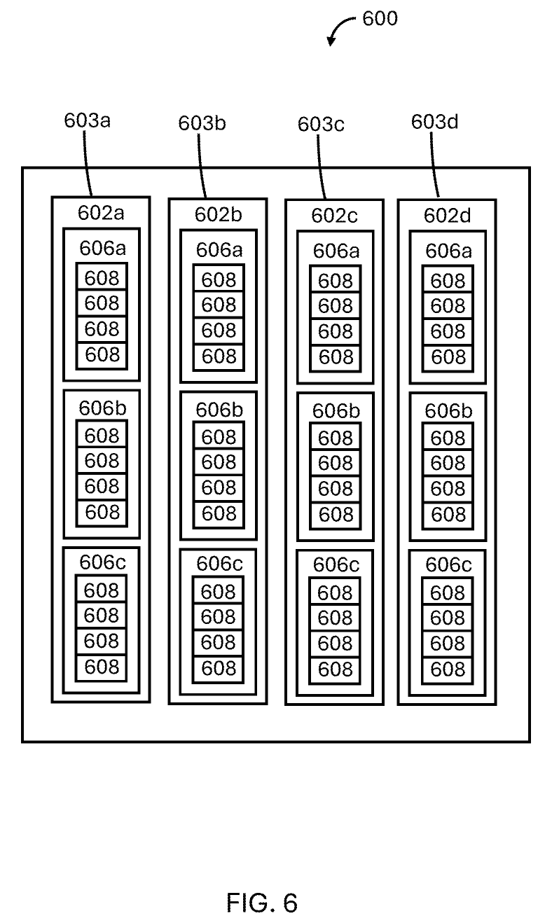

FIG. 6 illustrates a multi-plane WL 600 of a multi-plane block (e.g., the multi-plane block 500 of FIG. 5). The multi-plane WL 600 may include pages 602a, 602b, 602c, 602d. The pages 602a, 602b, 602c, 602d may be included in a set of physical blocks 603a, 603b, 603c, 603d that make up the multi-plane block. The pages 602a, 602b, 602c, 602d may be TLC pages that include TLC cells. Accordingly, each of the pages 602a, 602b, 602c, 602d may include an upper page 606a, a middle page 606b, and a lower page 606c. It would be appreciated by one of ordinary skill in the art that the pages 602a, 602b, 602c, 602d could include SLC pages, MLC pages, TLC, QLC pages, and/or PLC pages without departing from the spirit of the present disclosure. A plurality of data frames 608 may be stored in each of the upper pages 606a, middle pages 606b, and lower pages 606c. The data frames 608 may include user data, raw data, or filler data. The pages 602a, 602b, 602c, 602d may include good pages and one or more bad pages. The data frames 608 including the user data may be stored in the good pages. The data frames 608 including the raw data or filler data may be stored in the one or more bad pages.

FIG. 7 illustrates a data flow 700 for conservation of over provisioning through bad block handling. The data flow 700 includes data processors 702. The data processors 702 may be included in a controller (e.g., the controller 106 of FIG. 1) of a data storage system (e.g., the data storage system 104 of FIG. 1). The data processors 702 may perform various operations of an over provisioning conservation component (e.g., the over provisioning conservation component 112 of FIG. 1). The data processors may include a data scrambler 704, a CRC generator 706, and an LDPC encoder 708.

The data processors 702 may receive user data 712, process the user data 712 to generate processed user data, and provide the processed user data 712 to a buffer 710. The user data 712 may be received from a host system (e.g., the host system 102 of FIG. 1). The buffer 710 may be included in the controller. The data scrambler 704 may scramble data bits of user data 712. The CRC generator 706 may add CRC bits to the user data 712. The LDPC encoder 708 may add LDPC bits to the user data 712. The processed user data may be interleaved with raw data 714. The raw data 714 may be generated by the controller. The raw data 714 may have bit values corresponding to an erased state of a page, such as “111”, without limitation. The processed user data and the interleaved raw data 714 may be temporarily stored together in the buffer 710. Upon issuance of a bulk data transfer command and/or a random data input command, the processed user data and the interleaved raw data 714 may be released from the buffer 710 to a memory device 714.

FIG. 8 illustrates a data flow 800 for conservation of over provisioning through bad block handling. The data flow 800 includes data processors 802. The data processors 802 may be included in a controller (e.g., the controller 106 of FIG. 1) of a data storage system (e.g., the data storage system 104 of FIG. 1). The data processors 802 may perform various operations of an over provisioning conservation component (e.g., the over provisioning conservation component 112 of FIG. 1). The data processors 802 may include a data scrambler 804, a CRC generator 806, and an LDPC encoder 808.

The data processors 802 may receive user data 816 and filler data 818. The user data 816 may be received from a host system (e.g., the host system 102 of FIG. 1). The filler data 818 may be generated by the controller. The filler data 818 may have a fixed data pattern, such as all ones (1s) or all zeros (0s). The data processors 802 may process the user data 816 and the filler data 818 to generate processed user data and processed filler data. The processed user data may be provided to a buffer 810. The processed filler data may be provided to a buffer 812. The buffers 810, 812 may be included in the controller. The data scrambler 804 may scramble data bits of the user data 816 and the filler data 818. The CRC generator 806 may add CRC bits to the user data 816 and the filler data 818. The LDPC encoder 808 may add LDPC bits to the user data 816 and the filler data 818. The user data 816 and the filler data 818 may be processed by the data processors 802 either sequentially or in parallel. Upon issuance of a bulk data transfer command and/or a random data input command sequence, the processed user data and the processed filler data may be released from the buffers 810, 812 to a memory device 814.

Through hardware, software, firmware, or various combinations thereof, any of the processing elements (e.g., the controller 106 and/or local controller(s) of FIG. 1, the processing element 202 of FIG. 2, the controller 302 of FIG. 3, the data processors 702 of FIG. 7, and/or the data processors 802 of FIG. 8) may – alone or in combination with other processing elements – be configured to perform the operations of embodiments of the present disclosure. The embodiments described herein in connection with the attached drawing figures are intended to describe aspects of the disclosure in sufficient detail to enable those skilled in the art to practice the disclosure. Other embodiments can be utilized and changes can be made without departing from the scope of the present disclosure. The system may include additional, less, or alternate functionality and/or device(s), including those discussed elsewhere herein. The above and below detailed description is, therefore, not to be taken in a limiting sense. The scope of the present disclosure is defined only by the appended claims, along with the full scope of equivalents to which such claims are entitled, unless otherwise expressly stated and/or readily apparent to those skilled in the art from the description.

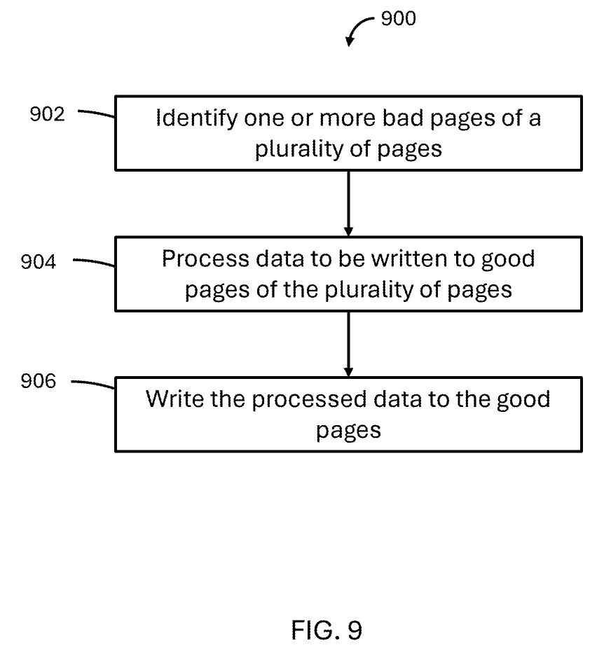

FIG. 9 illustrates an example method 900 for conservation of over provisioning through bad block handling. The method may be performed by a controller (e.g., the controller 106 and/or controller(s) 118 of FIG. 1) of a data storage system (e.g., the data storage system 104 of FIG. 1). The controller may manage storage and retrieval of data to and from a memory device (e.g., the memory device 114 of FIG. 1). The controller may receive read and write requests from a host system (e.g., the host system 102 of FIG. 1). Upon receiving a write request, the controller may facilitate writing data received from the host system to the memory device. Upon receiving a read request, the controller may facilitate reading of data from the memory device and communication of the data to the host system.

The method 900 may operate on a multi-plane block of an NVM described in more detail above in connection with FIGS. 1, 5, and 6. The controller may include data processors and buffers described in more detail above in connection with FIGS. 7 and 8.

At operation 902, one or more bad pages of a multi-plane WL (e.g., the multi-plane WL of FIG. 5) may be identified. The one or more bad pages may be included in the multi-plane WL. The multi-plane WL may be included in a multi-page block (e.g., the multi-plane block 500 of FIG. 5). The multi-plane WL may additionally include good pages. The good and bad page(s) may be identified by querying bad block information stored in the memory device. Bad blocks may be detected based on error information produced by the physical blocks. The bad block may include bad pages. The bad block information may be updated to include newly detected bad blocks each time a bad block is detected. The identified bad page(s) may be part of one or more bad blocks. Accordingly, the identification of the one or more bad pages may be made at the level of the physical block or at the level of the page, without limitation.

At operation 904, user data to be written to the good pages may be processed. The controller may include a data scrambler, a CRC generator, and an LDPC encoder. Processing the user data may include scrambling data bits of the user data by the data scrambler, adding CRC bits to the user data, and adding LDPC bits to the user data to generate processed user data. The controller may issue a random data input command sequence to transfer the processed user data to a first subset of the page registers corresponding to the good pages. The controller may issue a multi-plane full programming sequence to write the user data to the good pages.

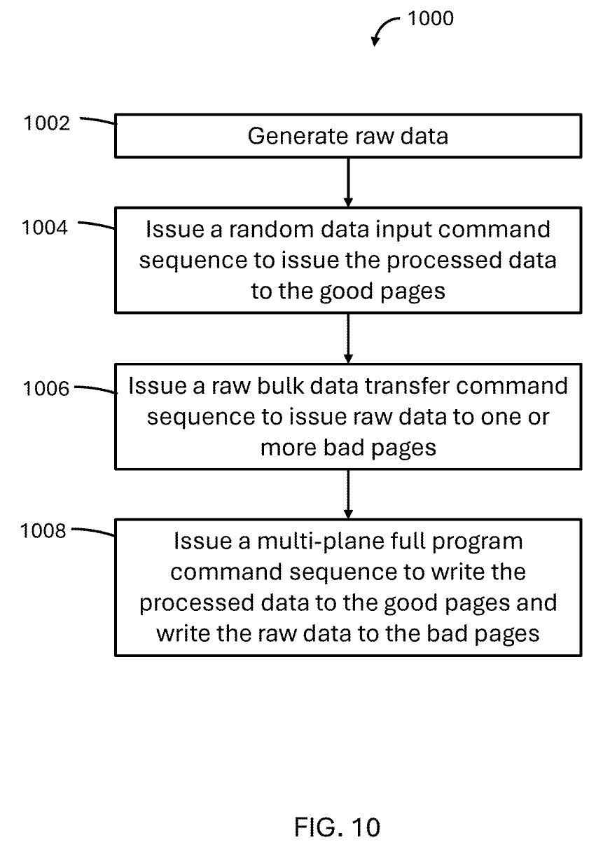

The controller may prevent user data from being written to the bad page(s). In various examples, raw data may be interleaved with the processed user data. The raw data may be issued to the bad page(s). The raw data may not be processed in the same manner as the user data. The bad page(s) may be in an erased state having a corresponding bit value. The raw data may have bit values corresponding to the erased state. Accordingly, the bad page(s) may remain in the erased state after the raw data is issued, and no programming operations may occur on the bad page(s). In this example, processing of the raw data may be skipped. Accordingly, the controller may prevent the processed user data form being written to the bad page(s). Further operations related to the raw data are described in detail with respect to FIG. 10.

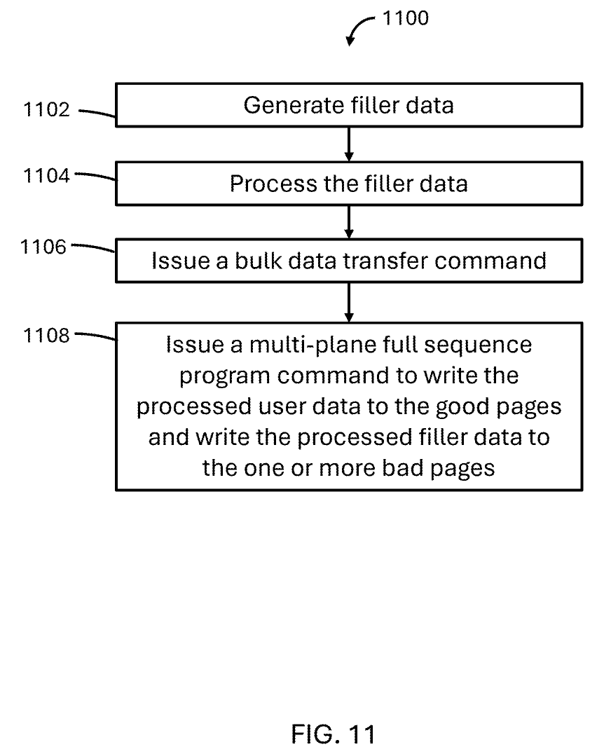

In various examples, it may not be possible or preferred to skip processing of the raw data. In such cases, filler data may be generated. The filler data may have a fixed data pattern, such as all zeros (0s) or all ones (1s). The filler data may be used in place of the raw data if the controller is unable or it is not preferred to skip processing of the raw data by the data scrambler, CRC generator, and LDPC encoder. For example, some legacy controllers may not be capable of interleaving raw data with processed data. In this example, the filler data may be processed in the same manner as the user data. The filler data and the user data may be processed either sequentially or in parallel. The filler data may be issued to the bad page(s), such that the bad page(s) are programmed to the fixed data pattern. Accordingly, the controller may prevent the processed user data from being written to the bad page(s). Further operations related to the filler data are described in detail with respect to FIG. 11.

FIG. 10 illustrates an example method 1000 for conservation of over provisioning through bad block handling wherein processing of raw data is skipped. The method 1000 may be performed in connection with the method 900 of FIG. 9, such as in connection with operation 906, and as otherwise described in more detail above. The method may be performed by a controller (e.g., the controller 106 and/or controller(s) 118 of FIG. 1) of a data storage system (e.g., the data storage system 104 of FIG. 1). The controller may manage storage and retrieval of data to and from a memory device (e.g., the memory device 114 of FIG. 1). The controller may receive read and write requests from a host system (e.g., the host system 102 of FIG. 1). Upon receiving a write request, the controller may facilitate writing data received from the host system to the memory device. Upon receiving a read request, the controller may facilitate reading of data from the memory device and communication of the data to the host system.

The method 1000 may operate on a multi-plane block of an NVM described in more detail above in connection with FIGS. 1, 5, and 6. The controller may include data processors and buffers described in more detail above in connection with FIGS. 7 and 8.

At operation 1002, raw data may be generated. The raw data may have a value corresponding to an erased state of bad page(s) (e.g., as described in more detail above in connection with FIGS. 1 and 7). The bad page(s) may be included in a multi-plane WL (e.g., the multi-plane WL 508 of FIG. 5). For example, the bit value of the erased state may be “111”. The bad page(s) may be in the erased state prior to issuance of the raw data.

At operation 1004, a random data input command sequence may be issued to issue processed user data (e.g., as described in operation 904 of FIG. 9) to good pages of the multi-plane WL. The processed user data may be issued to a set of page registers corresponding to the good pages.

At operation 1006, a raw bulk data transfer command sequence may be issued to issue the raw data to the page registers corresponding to the bad page(s). The raw data may be issued to a first subset of the page registers corresponding to the bad page(s). The raw bulk data transfer command sequence may be included in the random data input command sequence.

At operation 1008, a multi-plane full program command sequence may be issued to write the processed user data to the good pages and write the raw data to the bad page(s). Because the raw data has a same bit value as the erased state of the bad page(s), the bad page(s) may remain in the erased state after the multi-plane full program command sequence is completed. Consequently, the bad page(s) are not programmed with any data, and the bad page(s) are effectively skipped over when programming the processed user data to the good pages.

FIG. 11 illustrates an example method 1100 for conservation of over provisioning through bad block handling wherein filler data is processed along with user data. The method may be performed by a controller (e.g., the controller 106 and/or controller(s) 118 of FIG. 1) of a data storage system (e.g., the data storage system 104 of FIG. 1). The method 1100 may be performed in connection with the method 900 of FIG. 9, such as in connection with operation 904 and the operation 906, and as otherwise described in more detail above. The controller may manage storage and retrieval of data to and from a memory device (e.g., the memory device 114 of FIG. 1). The controller may receive read and write requests from a host system (e.g., the host system 102 of FIG. 1). Upon receiving a write request, the controller may facilitate writing data received from the host system to the memory device. Upon receiving a read request, the controller may facilitate reading of data from the memory device and communication of the data to the host system.

The method 1100 may operate on a multi-plane block of an NVM described in more detail above in connection with FIGS. 1, 5, and 6. The controller may include data processors and buffers described in more detail above in connection with FIGS. 7 and 8.

At operation 1102, filler data may be generated. The filler data may have a fixed data pattern, such as all zeros (0s) or all ones (1s).

At operation 1104, the filler data may be processed in the same manner as the user data described with reference to FIG. 9. Accordingly, a data scrambler may scramble bits of the filler data, a CRC generator may add CRC bits to the filler data, and an LDPC encoder may add LDPC bits to the filler data to generate processed filler data. The filler data may be processed either sequentially or in parallel with the user data.

At operation 1106, a bulk data transfer command sequence may be issued to transfer the processed user data to page registers corresponding to good pages and to transfer the processed filler data to one or more page registers corresponding to bad page(s). The good pages and the bad page(s) may be included in a multi-plane WL (e.g., the multi-plane WL 508 of FIG. 5).

At operation 1108, a multi-plane full program command sequence may be issued to write the processed data to the good pages and write the processed filler data to the bad page(s). The bad page(s) may be programmed to the fixed data pattern of the processed filler data. Consequently, the bad page(s) of the multi-plane block are effectively skipped when writing user data to the good pages of the multi-plane block.

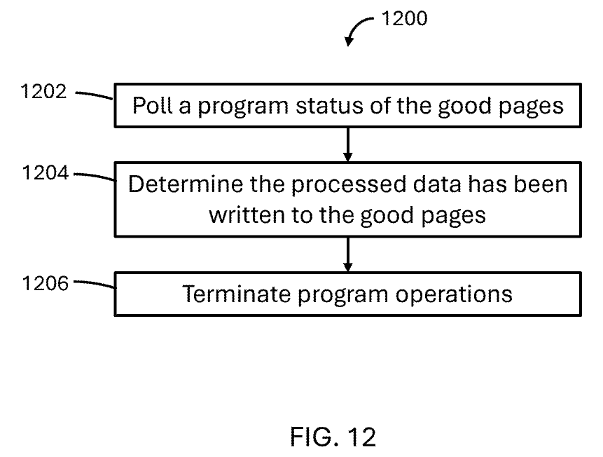

FIG. 12 illustrates an example method 1200 for completing write operations in connection with conservation of overprovisioning through bad block handling. The method may be performed by a controller (e.g., the controller 106 and/or controller(s) 118 of FIG. 1) of a data storage system (e.g., the data storage system 104 of FIG. 1). The method 1200 may be performed in connection with the method(s) of FIG. 9, FIG. 10, and/or FIG. 11, and as otherwise discussed in more detail above. For example, the method may be performed in connection with operation 906 of FIG. 9, operation 1008 of FIG. 10, and/or operation 1108 of FIG. 11. The controller may manage storage and retrieval of data to and from a memory device (e.g., the memory device 114 of FIG. 1). The controller may receive read and write requests from a host system (e.g., the host system 102 of FIG. 1). Upon receiving a write request, the controller may facilitate writing data received from the host system to the memory device. Upon receiving a read request, the controller may facilitate reading of data from the memory device and communication of the data to the host system.

The method 1200 may operate on a multi-plane block of an NVM described in more detail above in connection with FIGS. 1, 5, and 6. The controller may include data processors and buffers described in more detail above in connection with FIGS. 7 and 8.

At operation 1202, a program status of good pages may be polled. Polling the program status of the good pages may include supplying program verify voltages to respective WLs corresponding to the good pages. The respective WLs may be included in a multi-plane WL (e.g., the multi-plane WL 508 of FIG. 5). The controller may poll the program status of only the good pages. The controller may not poll the program status of the bad page(s).

At operation 1204, the controller may determine whether processed user data has been written to the good pages. Determining whether the processed user data has been written to the good pages may include measuring respective values of the cells of each good page in response to supplying the program verify voltages to the respective WLs. The controller may determine that the processed user data has been written to the good pages when the program status of each good page indicates that the user data was successfully written. The controller may continue polling the program status of the good pages until the program status of each good page indicates that the user data was successfully written.

At operation 1206, the controller may terminate program operations (e.g., a multi-plane full program command sequence) after determining that the processed user data has been written to the good pages. Polling the program status of only the good pages may reduce program time and improve program efficiency by skipping polling of the bad page(s).

Preventing writing of the processed user data to the bad page(s) may conserve over provisioning of the memory device by continuing to utilize good pages in a multi-plane block having good pages and bad pages. Conserving over provisioning may reduce write amplification of the memory device, avoid an increased number of P/E cycles caused by reduced over provisioning to extend the lifetime of the memory device, and maintain efficient write performance while effectively handling bad blocks.

### FEATURE COMBINATIONS

According to various examples of the present disclosure, a data storage system may include a controller, a memory, a non-volatile memory (NVM), and at least one processor. The NVM may include a logical unit (LUN). The LUN may include a set of planes. Each of the planes may include a physical block. Each of the physical blocks may include a wordline (WL). Each WL may include a page. The pages may include good pages and one or more bad pages. The physical blocks may be organized into a multi-plane block. The multi-plane block may include a multi-plane wordline (WL). The multi-plane WL may include the WLs of the physical blocks. The instructions, when executed by the at least one processor, may cause the at least one processor to: identify the one or more bad pages of the multi-plane WL; process user data to be written to the good pages of the multi-plane WL; and write the processed user data to the good pages. Writing of the processed user data to the good pages may include preventing writing of the processed user data to the one or more bad pages.

In combination with any of the previous examples, a data storage system may include a CRC generator, and an LDPC encoder. Processing of user data may include: scrambling, by the data scrambler, the data; subsequent to scrambling the user data, adding, by the CRC generator, CRC code to the user data; and subsequent to adding the CRC code, adding, by the LDPC encoder, LDPC code to the user data.

In combination with any of the previous examples, one or more bad pages may be in an erased state. Writing processed user data to good pages may include: generating raw data including a set of bits; and interleaving the raw data with processed user data. Each bit of the set of bits may have a value corresponding to the erased state.

In combination with any of the previous examples, a multi-plane block may include a set of page registers. Each page register of the page registers may correspond to one set of pages. Writing processed user data to good pages may include: issuing a random data input command sequence to transfer the processed user data to a first subset of the page registers; issuing a raw bulk data transfer command sequence to issue raw data to a second subset of the page registers; and issuing a multi-plane program command sequence to write the processed user data to the good pages and issue the raw data to one or more bad pages such that the one or more bad pages remain in an erased state after the multi-plane program command sequence is executed. The first subset of the page registers may correspond to the good pages. The second subset of the page registers may correspond to the one or more bad pages. The random data input command sequence may include the raw bulk data transfer command sequence.

In combination with any of the previous examples, writing processed user data to good pages may include: generating filler data having a fixed data pattern; scrambling, by a data scrambler, the filler data; subsequent to scrambling the filler data, adding, by a CRC generator, CRC code to the filler data; subsequent to adding the CRC code, adding, by an LDPC encoder, LDPC code to the filler data to generate processed filler data; and storing the processed filler data in a first buffer. Processing the user data may include storing the processed user data in a second buffer.

In combination with any of the previous examples, a multi-plane block may include a set of page registers. Each of the page registers may correspond to a respective set of pages. Writing processed user data to good pages may include: issuing a bulk data transfer command sequence to issue processed user data to a first subset of the page registers and transfer processed filler data to a second subset of the page registers; and issuing a multi-plane program command sequence to write the processed user data to the good pages and write the processed filler data to the one or more bad pages. The first subset of the page registers may correspond to the good pages. The second subset of the page registers may correspond to the one or more bad pages.

In combination with any of the previous examples, instructions, when executed by at least one processor, may cause the at least one processor to: poll a program status of good pages and skip polling of the program status of one or more bad pages; and determine that processed user data has been written to the good pages based on the polled program status of the good pages.

According to various examples of the present disclosure, a computer implemented method may include: identifying one or more bad pages of a multi-plane WL of a multi-plane block of an NVM; processing user data to be written to good pages of the multi-plane WL; and writing the processed user data to the good pages. The NVM may include a LUN. The LUN may include a set of planes. Each of the planes may include a physical block. Each of the physical blocks may include a WL. Each of the WLs may include a page. The pages may include the good pages and the one or more bad pages. The physical blocks may be organized into the multi-plane block. The multi-plane WL may include the WLs of the physical blocks. Writing of the processed user data to the good pages may include preventing writing of the processed user data to the one or more bad pages.

According to various examples of the present disclosure, non-transitory media may include instructions stored thereon, that when executed by at least one processor, may cause the at least one processor to: identify one or more bad pages of a multi-plane WL of a multi-plane block of an NVM; process user data to be written to good pages of the multi-plane WL; and write the processed user data to the good pages. The NVM may include a LUN. The LUN may include a set of planes. Each of the planes may include a physical block. Each of the physical blocks may include a WL. Each of the WLs may include a page. The pages may include the good pages and the one or more bad pages. The physical blocks may be organized into the multi-plane block. The multi-plane WL may include the WLs of the physical blocks. Writing of the processed user data to the good pages may include preventing writing of the processed user data to the one or more bad pages.

### GENERAL CONSIDERATIONS

In this description, references to “one embodiment”, “an embodiment”, “embodiments”, “an example”, “one example”, or “examples” mean that the feature or features being referred to are included in at least one embodiment or example of the technology. Separate references to “one embodiment”, “an embodiment”, “embodiments”, “an example”, “one example”, or “examples” in this description do not necessarily refer to the same embodiment or example and are also not mutually exclusive unless so stated and/or except as will be readily apparent to those skilled in the art from the description. For example, a feature, structure, act, etc. described in one embodiment may also be included in other embodiments but is not necessarily included. Thus, the current technology can include a variety of combinations and/or integrations of the embodiments described herein.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein, unless otherwise expressly stated and/or readily apparent to those skilled in the art from the description.

Certain embodiments are described herein as including logic or a number of routines, subroutines, applications, or instructions. These may constitute either software (e.g., code embodied on a machine-readable medium or in a transmission signal) or hardware. In hardware, the routines, etc., are tangible units capable of performing certain operations and may be configured or arranged in a certain manner. In example embodiments, one or more computer systems (e.g., a standalone, client or server computer system) or one or more hardware modules of a computer system (e.g., a processor or a group of processors) may be configured by software (e.g., an application or application portion) as computer hardware that operates to perform certain operations as described herein.

In various embodiments, computer hardware, such as a processing element, may be implemented as special purpose or as general purpose. For example, the processing element may comprise dedicated circuitry or logic that is permanently configured, such as an application-specific integrated circuit (ASIC), or indefinitely configured, such as an FPGA, to perform certain operations. The processing element may also comprise programmable logic or circuitry (e.g., as encompassed within a general-purpose processor or other programmable processor) that is temporarily configured by software to perform certain operations. It will be appreciated that the decision to implement the processing element as special purpose, in dedicated and permanently configured circuitry, or as general purpose (e.g., configured by software) may be driven by cost and time considerations.

Accordingly, the term “processing element” or equivalents should be understood to encompass a tangible entity, be that an entity that is physically constructed, permanently configured (e.g., hardwired), or temporarily configured (e.g., programmed) to operate in a certain manner or to perform certain operations described herein. Considering embodiments in which the processing element is temporarily configured (e.g., programmed), each of the processing elements need not be configured or instantiated at any one instance in time. For example, where the processing element comprises a general-purpose processor configured using software, the general-purpose processor may be configured as respective different processing elements at different times. Software may accordingly configure the processing element to constitute a particular hardware configuration at one instance of time and to constitute a different hardware configuration at a different instance of time.

Computer hardware components, such as communication elements, memory elements, processing elements, and the like, may provide information to, and receive information from, other computer hardware components. Accordingly, the described computer hardware components may be regarded as being communicatively coupled. Where multiple of such computer hardware components exist contemporaneously, communications may be achieved through signal transmission (e.g., over appropriate circuits and buses) that connect the computer hardware components. In embodiments in which multiple computer hardware components are configured or instantiated at different times, communications between such computer hardware components may be achieved, for example, through the storage and retrieval of information in memory structures to which the multiple computer hardware components have access. For example, one computer hardware component may perform an operation and store the output of that operation in a memory device to which it is communicatively coupled. A further computer hardware component may then, at a later time, access the memory device to retrieve and process the stored output. Computer hardware components may also initiate communications with input or output devices, and may operate on a resource (e.g., a collection of information).

The various operations of example methods described herein may be performed, at least partially, by one or more processing elements that are temporarily configured (e.g., by software) or permanently configured to perform the relevant operations. Whether temporarily or permanently configured, such processing elements may constitute processing element-implemented modules that operate to perform one or more operations or functions. The modules referred to herein may, in some example embodiments, comprise processing element-implemented modules.

Similarly, the methods or routines described herein may be at least partially processing element-implemented. For example, at least some of the operations of a method may be performed by one or more processing elements or processing element-implemented hardware modules. The performance of certain of the operations may be distributed among the one or more processing elements, not only residing within a single machine, but deployed across a number of machines. In some example embodiments, the processing elements may be located in a single location (e.g., within a home environment, an office environment or as a server farm), while in other embodiments the processing elements may be distributed across a number of locations.

Unless specifically stated otherwise, discussions herein using words such as “processing,” “computing,” “calculating,” “determining,” “presenting,” “displaying,” or the like may refer to actions or processes of a machine (e.g., a computer with a processing element and other computer hardware components) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The patent claims at the end of this patent application are not intended to be construed under 35 U.S.C. § 112(f) unless traditional means-plus-function language is expressly recited, such as “means for” or “step for” language being explicitly recited in the claim(s).

Although the invention has been described with reference to the embodiments illustrated in the attached drawing figures, it is noted that equivalents may be employed and substitutions made herein without departing from the scope of the invention as recited in the claims.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

What is claimed is:

1. A data storage system including a controller, comprising:
memory including instructions stored thereon;
a non-volatile memory (NVM), said NVM including a logical unit (LUN), said LUN including a set of planes, each of said planes including a physical block, each of said physical blocks including a wordline (WL), each of said WLs including a page, said pages including good pages and one or more bad pages, said physical blocks being organized into a multi-plane block, said multi-plane block including a multi-plane wordline (WL), said multi-plane WL including the WLs of the physical blocks; and
at least one processor, wherein said instructions, when executed by the at least one processor, cause the at least one processor to:
identify the one or more bad pages;
process user data to be written to the good pages; and
write the processed user data to the good pages, wherein said writing of the processed user data to the good pages includes preventing writing of the processed user data to the one or more bad pages.

2. The data storage system of claim 1,
comprising a data scrambler, a cyclic redundancy check (CRC) generator, and a low-density parity-check (LDPC) encoder,
wherein said processing of the user data includes:
scrambling, by the data scrambler, the user data;
subsequent to scrambling the user data, adding, by the CRC generator, CRC code to the user data; and
subsequent to adding the CRC code, adding, by the LDPC encoder, LDPC code to the user data.

3. The data storage system of claim 1,
said one or more bad pages being in an erased state,
wherein said writing of the processed user data to the good pages includes:
generating raw data including a set of bits, each bit of said set of bits having a value corresponding to the erased state; and
interleaving the raw data with the processed user data.

4. The data storage system of claim 3,
said multi-plane block including a set of page registers, each page register of said set of page registers corresponding to one the pages,
wherein said writing of the processed user data to the good pages includes:
issuing a random data input command sequence to transfer the processed user data to a first subset of the page registers, said first subset of the page registers corresponding to the good pages;
issuing a raw bulk data transfer command sequence to transfer the raw data to a second subset of the page registers, said second subset corresponding to the one or more bad pages; and
issuing a multi-plane program command sequence to write the processed user data to the good pages and issue the raw data to the one or more bad pages such that the one or more bad pages remain in the erased state after the multi-plane program command sequence is executed,
said random data input command sequence including the raw bulk data transfer command sequence.

5. The data storage system of claim 2,
wherein said writing of the processed user data to the good pages includes:
generating filler data having a fixed data pattern;
scrambling, by the data scrambler, the filler data;
subsequent to scrambling the filler data, adding, by the CRC generator, CRC code to the filler data;
subsequent to adding the CRC code, adding, by the LDPC encoder, LDPC code to the filler data to generate processed filler data; and
storing the processed filler data in a first buffer,
wherein said processing of the user data includes storing the processed user data in a second buffer.

6. The data storage system of claim 5,
said multi-plane block including a set of page registers, each of said page registers corresponding to one the pages,
wherein said writing of the processed user data to the good pages includes:
issuing a bulk data transfer command sequence to transfer the processed user data to a first subset of the page registers, said first subset corresponding to the good pages, and to transfer the processed filler data to a second subset of the page registers, said second subset corresponding to the one or more bad pages; and
issuing a multi-plane program command sequence to write the processed user data to the good pages and write the processed filler data to the one or more bad pages.

7. The data storage system of claim 1,
wherein the instructions, when executed by the at least one processor, cause the at least one processor to:
poll a program status of the good pages and skip polling of the program status of the one or more bad pages; and
determine that the processed user data has been written to the good pages based on the polled program status of the good pages.

8. A computer-implemented method, comprising:
identifying one or more bad pages of a multi-multi-plane wordline (WL) of a multi-plane block of a non-volatile memory (NVM), said NVM including a logical unit (LUN), said LUN including a set of planes, each of said planes including a physical block, each of said physical blocks including a wordline (WL), each of said WLs including a page, said pages including good pages and the one or more bad pages, said physical blocks being organized into the multi-plane block, said multi-plane WL including the WLs of the physical blocks;
processing user data to be written to the good pages; and
writing the processed user data to the good pages, wherein said writing of the processed user data to the good pages includes preventing writing of the processed user data to the one or more bad pages.

9. The computer-implemented method of claim 8,
wherein said processing of the user data includes:
scrambling the user data;
subsequent to scrambling the user data, adding cyclic redundancy check (CRC) code to the user data; and
subsequent to adding the CRC code, adding, low-density parity-check (LDPC) code to the user data.

10. The computer-implemented method of claim 8,
said one or more bad pages being in an erased state,
wherein said writing of the processed user data to the good pages includes:
generating raw data including a set of bits, each bit of said set of bits having a value corresponding to the erased state; and
interleaving the raw data with the processed user data.

11. The computer-implemented method of claim 10,
said multi-plane block including a set of page registers, each page register of said set of page registers corresponding to one of the pages,
wherein said writing of the processed user data to the good pages includes:
issuing a random data input command sequence to transfer the processed user data to a first subset of the page registers, said first subset of the page registers corresponding to the good pages;
issuing a raw bulk data transfer command sequence to transfer the raw data to a second set of the page registers, said second subset of the page registers corresponding to the one or more bad pages; and
issuing a multi-plane program command sequence to write the processed user data to the good pages and issue the raw data to the one or more bad pages such that the one or more bad pages remain in the erased state after the multi-plane program command sequence is executed,
said random data input command sequence including the raw bulk data transfer command sequence.

12. The computer-implemented method of claim 9,
wherein said writing of the processed user data to the good pages includes:
generating filler data having a fixed data pattern;
scrambling, by the data scrambler, the filler data;
subsequent to scrambling the filler data, adding CRC code to the filler data;
subsequent to adding the CRC code LDPC code to the filler data to generate processed filler data; and
storing the processed filler data in a first buffer,
wherein said processing of the user data includes storing the processed user data in a second buffer.

13. The computer implemented method of claim 12,
said multi-plane block including a set of page registers, each page register of said set of page registers corresponding to one of the pages,
wherein said writing of the processed user data to the good pages includes:
issuing a bulk data transfer command sequence to transfer the processed user data to a first subset of the page registers, said first subset of the page registers corresponding to the good pages and transfer the processed filler data to a second subset of the page registers, said second subset of the page registers corresponding to the one or more bad pages; and
issuing a multi-plane program command sequence to write the processed user data to the good pages and write the processed filler data to the one or more bad pages.

14. The computer implemented method of claim 8, comprising:
polling a program status of the good pages and skipping polling of the program status of the one or more bad pages; and
determining that the processed user data has been written to the good pages based on the polled program status of the good pages.

15. Non-transitory computer readable media having instructions stored thereon, that when executed by at least one processor, cause the at least one processor to:
identify one or more bad pages of a multi-plane wordline (WL) of a multi-plane block of a non-volatile memory (NVM), said NVM including a logical unit (LUN), said LUN including a set of planes, each of said planes including a physical block, each of said physical blocks including a wordline (WL), each of said WLs including a page, said pages including good pages and the one or more bad pages, said physical blocks being organized into the multi-plane block, said multi-plane WL including the WLs of the physical blocks;
process user data to be written to the good pages; and
write the processed user data to the good pages, wherein said writing of the processed user data to the good pages includes preventing writing of the processed data to the one or more bad pages.

16. The non-transitory computer readable media of claim 15,
wherein processing the data includes:
scrambling the user data;
subsequent to scrambling the user data, adding cyclic redundancy check (CRC) code to the user data; and
subsequent to adding the CRC code, adding low-density parity-check (LDPC) code to the user data.

17. The non-transitory computer readable medium of claim 15,
said one or more bad pages being in an erased state,
wherein said writing of the processed user data to the good pages includes:
generating raw data including a set of bits, each bit of said set of bits having a value corresponding to the erased state; and
interleaving the raw data with the processed user data.

18. The non-transitory computer readable media of claim 17,
said multi-plane block including a set of page registers, each page register of said set of page registers corresponding to one of the pages,
wherein said writing of the processed user data to the good pages includes:
issuing a random data input command sequence to transfer the processed user data to respective ones of set of the page registers corresponding to the good pages;
issuing a raw bulk data transfer command sequence to transfer the raw data to respective ones of the set of page registers corresponding to the one or more bad pages; and
issuing a multi-plane program command sequence to write the processed user data to the good pages and issue the raw data to the one or more bad pages such that the one or more bad pages remain in the erased state after the multi-plane program command sequence is executed,
said random data input command sequence including the raw bulk data transfer command sequence.

19. The non-transitory computer readable media of claim 16,
wherein said writing of the processed user data to the good pages includes:
generating filler data having a fixed data pattern;
scrambling, by the data scrambler, the filler data;
subsequent to scrambling the filler data, adding CRC code to the filler data;
subsequent to adding the CRC code, adding LDPC code to the filler data to generate processed filler data; and
storing the processed filler data in a first buffer,
wherein said processing of the user data includes storing the processed user data in a second buffer.

20. The non-transitory computer readable medium of claim 19,
said multi-plane block including a set of page registers, each page register of said set of page registers corresponding to one of the pages,
wherein said writing of the processed user data to the good pages includes:
issuing a bulk data transfer command sequence to transfer the processed user data to a first subset of the page registers, said first subset of the page registers corresponding to the good pages and transfer the processed filler data to a second subset of the page registers, said second subset of the page registers corresponding to the one or more bad pages; and
issuing a multi-plane program command sequence to write the processed user data to the good pages and write the processed filler data to the one or more bad pages.
